(19) United States
(12) Patent Application Publication
(10) Pub. No.: US 2009/0050204 A1
(43) Pub. Date: Feb. 26, 2009

(54) PHOTOVOLTAIC DEVICE USING NANOSTRUCTURED MATERIAL

(75) Inventor: Youssef Habib, Lancaster, PA (US)

Correspondence Address: TED SABETY, c/o Sabety +associates, PLLC, 1130 Bedford Rd., PLEASANTVILLE, NY, 10570, US

(73) Assignee: Illuminex Corporation.

(21) Appl. No.: 12/185,773

(22) Filed: Aug. 4, 2008

Related U.S. Application Data
(60) Provisional application No. 60/953,752, filed on Aug. 3, 2007.

(51) Int. Cl. H01L 31/00

(52) U.S. Cl. 136/261; 257/E31.001

(57) ABSTRACT

A photovoltaic device where the charge carrier collection occurs in an array of semiconducting nanowires. The structure of the nanowire array enables high conversion efficiency devices to be built at low cost. In one embodiment, the single crystal silicon nanowire elements can be 10-100 microns long, 50-300 nm in diameter, and spaced 100-400 nm center-to-center. Larger or smaller dimensions can be selected with varying results. The nanowire cores are electrically connected to each other through the conductive substrate on the base of the device. A transparent conductor to be applied on top of the n-type layer will form the second electrode.

This patent application hereby incorporates by reference and claims priority to U.S. Patent Application Nos. 60/953,752 filed on Aug. 3, 2007 and to Ser. No. 11/917,505 filed on Dec. 14, 2007, the U.S. National Stage of PCT/US06/023662 filed on Jun. 16, 2006, with priority to 60/692,202 filed on Jun. 17, 2005.

This invention was supported in part by U.S. Government STTR contract number #DE-FG02-07ER86313, awarded by DOE and portions of this invention may be subject to a paid-up license to the U.S. Government.

### SUMMARY OF THE INVENTION

The invention is a low cost processing technique for the fabrication of radial p-n silicon nanowire arrays and a nanowire-based photovoltaic device. The structure of the nanowire array enables high conversion efficiency devices to be built at low cost. The high conversion efficiency of the device is a result of two properties inherent to the nanowire array architecture: 1) the nanowires are an effective light trap and have very high absorption across the solar band; and 2) carrier extraction is enhanced by the large junction surface that has a small extraction distance. In other words, the nanowires are optically thick (along the nanowire axis) and electronically thin (in the radial direction). The low cost is a result of using inexpensive precursor materials and minimal amounts of silicon.

In one embodiment, the single crystal silicon nanowire elements can be 10-100 μm long, 50-300 nm in diameter, and spaced 100-400 nm center-to-center. Larger or smaller dimensions can be selected with varying results. The p-type nanowire cores are electrically connected to each other through the conductive substrate on the base of the device. A transparent conductor to be applied on top of the n-type layer will form the second electrode. Each wire in the array comprises a p-type core section and an n-type outer layer also shown schematically in FIG. 1. The invention works with the p-type and n-type layers reversed.

### BRIEF DESCRIPTION OF THE DRAWINGS

FIG. 1. Schematic of the nanowire PV device (left) and an individual nanowire (right). The pn-junction is formed along the length of the nanowire.

FIG. 2. SEM micrograph showing the constituent layers of a nanowire substrate.

FIG. 3. Schematic illustration of photon paths within the nanowire matrix.

FIG. 4. This schematic shows a cross-section of a porous anodic aluminum oxide film on Al metal.

FIG. 5. SEM of Silicon nanowires grown on an ITO coated galls substrate using the AAO templating technique.

FIG. 6. SEM micrographs showing the Al substrate, gold seeds, AAO and silicon nanowires (left) and a top view of silicon nanowires on Al (right).

FIG. 7. SEM image of a glass substrate showing the ITO and Al coating layers.

FIG. 8. (Left) This SEM micrograph shows a top view of an AAO template produced on an ITO coated glass substrate by Illuminex. The pores are approximately 50 nm in diameter. (Right) This micrograph shows a cross-sectional view of porous AAO at the ITO interface showing the well formed, aligned channels.

FIG. 9. Schematic representation of the anodization and seeding process. (a) An as formed nanochannel in aluminum oxide at “high” voltage. (b) Continued anodization at “low” voltage creates tiny nanofingers at the channel bottom. (c) Phosphoric acid etch solution widens the channel to the desired diameter while removing the insulating Al₂O₃ barrier layer. (d) Electrodeposition is used to seed each channel with gold.

FIG. 10. Anodized Al with gold seeds.

FIG. 11. Silicon-gold phase diagram. The low temperature eutectic is critical for the VLS growth process.

FIG. 12. (top) Simplified 3-D schematic of 4-point test structure. (bottom) FE-SEM image of four-point back-gated test structure used to characterize SiNW resistivity

FIG. 13 (Left) Four-point resistivity of Si nanowires grown in AAO. The error bars represent the distribution of resistivities calculated from four-point resistance data collected on more than ten samples at each gas flow ratio. The carrier type was determined from gate-dependent conductance measurements where squares and triangles are used to denote p- and n-type, respectively. All measurements were conducted in a N₂ purged chamber. (Right) Phosphorus and boron concentration in Si nanowires obtained by SIMS measurements as a function of the dopant to Si ratio in the inlet gas.

FIG. 14. Absorption spectrum of a Si nanowire array.

FIG. 15. I-V plot of oxidized single vertical p-n Si nanowire junction. The p segment is doped at 2×10⁻³ TMB:SiH₄, and the n segment at 2×10⁻⁴ PH₃:SiH₄.

FIG. 16. Schematic representation of the structures produced.

### DETAILED DESCRIPTION OF THE PREFERRED EMBODIMENTS

### Solar Energy as an Electrical Energy Source

Photovoltaics hold great promise to help accommodate mankind's ever increasing levels of energy consumption. The sun is the ultimate energy source for all life on earth, and the generation of solar electricity is currently an under-utilized technology. Silicon based solar cells are the bastion of the current photovoltaic industry, however, they are not cost competitive with other forms of energy, in particular, fossil fuels. New innovations in photovoltaic design enabled by nanotechnology hold much promise for the engineering of solar cells with higher efficiency, lower cost, and greater flexibility for implemented design.

The utilization of abundant solar energy is becoming critical as the environmental, economic, political, and physiological impact of current energy strategies become an increasingly serious burden on society. The continued heavy usage of fossil fuels energy is exacting a heavy toll on the United States and the entire world. The United States is the largest user of fossil fuels, and the largest producer of green house gases. The environmental impact of burning oil is becoming more apparent everyday, as is the political impact of being dependent on foreign oil sources. The photovoltaic conversion (PV) of sunlight to electricity is one of the most attractive and sensible alternative energy sources imaginable. Solar power is not going to run out and is abundant enough to meet all of humanities foreseeable needs. To date, the major roadblock to the wide spread use of solar electricity is the cost, as much as ten times that of fossil fuel sources. Today, the price of solar systems installed is about $5/Wp in the United States. The Watt Power (Wp) output of a Solar module is the number of Watts Output when it is illuminated under standard conditions of 1000 Watts/meter² intensity, 25° C. ambient temperature and a spectrum that relates to sunlight that has passed through the atmosphere (AM or Air Mass 1.5). When amortized over a twenty year lifetime of a solar system, the price is 20-40 cents per kWh to generate solar electricity compared to 5-10 cents from the electric power companies, approximately a 4 fold difference. The proposed nanotechnology enabled solar cells could help bring the cost of solar power down to more competitive levels and induce more widespread usage of the technology.

Technologies that make PV power more cost competitive will have a very positive impact on society. The primary application for the nanowire PV technology is the delivery of clean efficient point-of-use electric power to systems and consumers. The major limitation to widespread commercial use of solar power in the developed world is the relatively high generation cost compared to burning fossil fuels. We anticipate that the combination of the increased conversion efficiency of the nanowire technology and lower overall manufacturing cost of solar panels using the technology will bring the generation cost of solar power into the $0.10 to 0.18/kWh range. Successful demonstration of the technology would make solar power competitive with fossil fuels for commercial electric generation and in the range suggested by the DOE Solar Energies Technology Program: Solar America Initiative.

The primary near term PV application in the US market will be “peak shaving” by using solar power to offset the premium cost for power in the afternoon. In many major urban centers in the US, utilities may pay in excess of $1/kWh to power suppliers during peak usage hours (typically 1 PM to 5 PM local time) to meet local demand. The cost of peak demand power will only increase in the coming years as demand is expected to continue to increase at a rate of nearly 5 percent per year, generation within urban centers remains stagnant and deregulation of the power industry allows market forces to dictate costs to consumers. These market conditions make solar electric generation competitive precisely at the time when solar power generation is most efficient. The return on the investment in solar generating capacity will be vastly improved under these conditions compared to the present and makes solar generation a viable means for controlling costs for electricity for both the residential and business customers.

Remote electric power systems are the second major near term application area. Increasing use of solar generation for remote applications in the developing world including: water treatment, irrigation and cellular telephone towers represent the large markets within this segment. Large investments in generating capacity are not made because of political instability and lack of a power distribution infrastructure. Despite the high cost, solar generating capacity in the third world is nearly doubling every year accounting for most of the 25-30 percent growth in the global demand for solar power.

### Nanostructured Photovoltaic Devices.

In recent years, a large body of scientific research has been performed on various nanotechnology approaches to photovoltaics utilizing both organic and inorganic materials. Gratzel has developed a dye sensitized solar cell using wide band gap TiO₂ nano-crystalline films coupled to the dye sensitizer and an electrolytic charge transfer mediator. The Gratzel cell has demonstrated solar conversion efficiencies over 10%, is amiable to low cost manufacture on flexible substrates, and is currently being manufactured by Konarka, Lowell Mass. However, the Gratzel approach is not as efficient as silicon and has lifetime issues associated with solar degradation of polymer substrates and gel electrolytes, thus, uncertainties remain.

Other approaches utilize nanoparticle/polymer hybrid heterojunctions such as CdSe nanorods or C₆₀ (fullerenes) embedded in an organic polymer matrix. This type of solar cell utilizes the interaction of nanoparticles dispersed at distances similar to the exciton diffusion length in the conjugated polymer. The nanoparticle/polymer hybrids show promise for ease of low-cost manufacture and flexibility, however, they suffer from lower conversion efficiencies, and great uncertainty concerning effective lifetimes due to UV degradation of the polymers.

Thin film photovoltaics are being developed as a way to bring down production cost and engineer lightweight and flexible solar cells. For example, NanoSolar has recently secured $100 million in funding to build a production facility and manufacture thin film CIGS (Copper Indium Gallium Diselenide) solar cells. CIGS thin film solar cells have the highest efficiencies of any thin film devices with cells approaching 18.5%. Crystalline silicon (c-Si) has an efficiency of 24.7%, while the highest efficiencies come from multi-junction devices such as GaInP/GaAs/Ge (32%). Efficiency in this proposal refers to the percentage of optical power that is converted to electrical power in a laboratory cell without module and other loss considerations. There is a constant trade off between efficiency, cost, and practicality of use. A significant, and often unstated, parameter is the difference between efficiencies measured in the laboratory and those obtained in the field after years of use. In this regard, the stability of c-Si is superior to competitive approaches.

Nanostructured Crystalline Silicon Devices.

Recently, Atwater et al. theorized that improvements in silicon solar cell performance (efficiency) could be realized by engineering vertically aligned (radial) p-n junction nanorod arrays which take advantage of both the narrow width of nanowires to improve carrier collection and the high aspect ratio to enhance light absorption. By properly engineering size and dopant concentration of the nanorod devices, calculations show that gains in efficiency of 1.5-13% can be attained compared to planar silicon solar cells.

Silicon is one of the most studied materials on earth and represents the largest class of solar cells currently under production with 95% of the market utilizing semiconductor grade silicon. Illuminex has extensive experience in processing nanowire arrays made from silicon and other materials, and thus, proposes for intends to engineer silicon nanowire (nanorod) materials for solar cells applications on aluminum and glass substrates. The use of crystalline silicon nanowires will reduce the amount of silicon used in production (compared to planar cells) while simultaneously increasing the efficiency of conversion. This innovative design makes it possible to construct large area photovoltaic panels that have high power density (specific power) in excess of 1000 W/kg.

In one embodiment of the invention, silicon nanowires on aluminum sheet are grown. In another embodiment, they are grown on indium-tin-oxide (ITO) coated glass substrates. Control over the nanowire diameter is achieved by using a porous anodic aluminum oxide (AAO) templating technique that first involves anodizing an Al layer to form nanoporous AAO with pores fully penetrating to a conductive substrate (ITO or Al). After forming the AAO, a gold catalytic seed that initiates the nanowire growth is inserted into the bottom of the pores. Then, single crystal p-type nanowires are grown using a vapor-liquid-solid (VLS) catalytic growth technique such that the nanowires extend beyond the AAO surface. The exposed portion of the p-type nanowires will then be fully coated with an n-type layer by chemical vapor deposition (CVD). In one embodiment, the aluminum or ITO substrate will form one electrode and a transparent coating of either a conductive oxide or a fullerene based conductor will be applied over the nanowires as the second electrode. The presence of the AAO layer provides a template to control the diameter and spacing of the nanowires, and further serves as a barrier to diffusion of p-type impurities from the substrate into the n-type layer and electrically isolates the two junction electrodes.

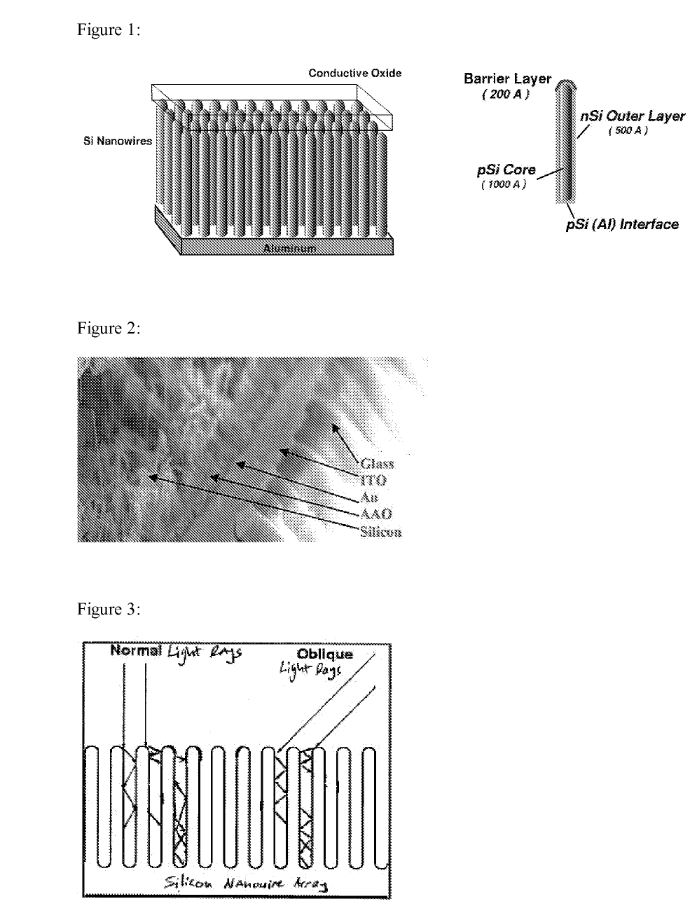

FIG. 2 shows a cross-sectional SEM image of a nanowire substrate with the glass, ITO, Au, AAO, and silicon nanowire layers visible. Similar substrates can be used as the basis of the proposed PV device.

Another embodiment of the invention is a nanowire array p-n junction PV device using crystalline silicon nanowire arrays that demonstrate PV diode behavior as evidenced by (current-voltage) I-V curves and the presence of a photocurrent when the device is illuminated. The nanowire processing technique uses an AAO template to initiate nanowire growth of a controlled and uniform diameter. The AAO template is produced using a low cost electrochemical process. Other templates can be used, including pre-made filter templates that are attached to the surface of the substrate. Any template that is inert to the crystal growth process may be used. In the preferred embodiment, the radial junctions are formed using metal-catalyzed vapor-liquid solid growth to form the p-type Si nanowire core followed by epitaxial deposition of an n-type Si layer on the outer surface of the wire via chemical vapor deposition. Other techniques of depositing the n-type Si layer may be used. In another embodiment, other n-type layers may be used as well, and deposited chemically or by evaporation.

Collection of the electrons and holes generated by absorbed photons should be superior to both polycrystalline and single crystal silicon PV devices since every electron-hole pair will be created within the high field region of the p-n junction depletion region. The short junction length combined with the single crystal nature of each nanowire will insure that the devices possess an extremely low series resistance and have large minority carrier lifetimes. The short junction distance also minimizes the forward recombination current and its deleterious effect on collected photocurrent.

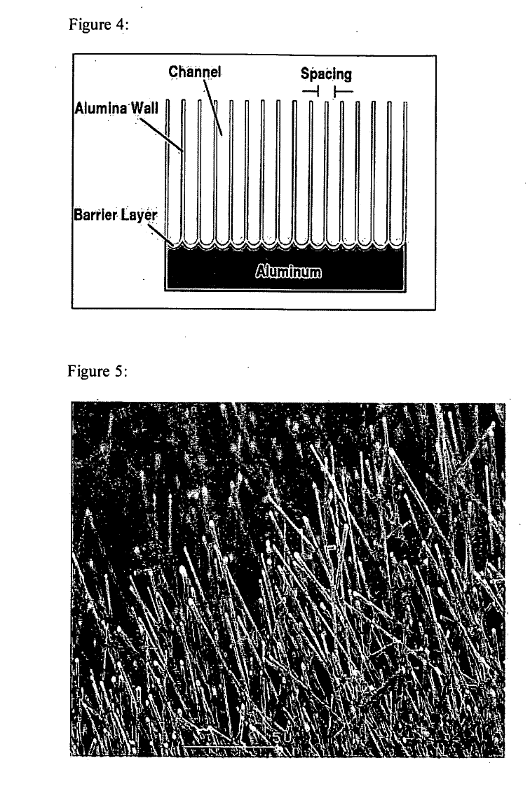

The light collection efficiency of the nanowire PV can rival that of textured crystalline devices. The array of nanowires acts as a wavelength independent light trap that will improve absorption of light across the entire solar band. The essential features of the light trap are the textured tops of the nanowires and the high extinction structures formed by the array of wires. Light entering the structure and reflecting from the top of a nanowire will be scattered into the plane of the device as shown in FIG. 4.

The nanowire array will take the textured surface to an extreme where most of the incident light will be reflected into the wire matrix to enhance total absorption in a physically thin structure.

It is well established that electrochemical oxidation of Al metal can result in the “self-assembled” growth of nanoporous AAO in which the diameter, depth, and spacing of the nanopores can be controlled by varying the anodization voltage and the electrolytic chemical types and concentrations used. The AAO will serve as a template for the formation of nanometer scale diameter silicon nanowires and will also function to electrically isolate the substrate conductor in contact with the p-type core from the upper conductor in contact with the n-type coating layer.

FIG. 5 shows a schematic of porous AAO on Al metal. During anodization, the pores openings are separated from the Al by a barrier oxide layer. This barrier layer is present when ITO coated glass is used as a substrate as well, although it is substantially thinner at the Al₂O₃/ITO interface than an Al₂O₃/Al one. The barrier layer is removed electrochemically prior to nanowire growth to ensure electrical contact between the nanowires and the substrate.

In the preferred embodiment, the growth of the silicon nanowires in an AAO template utilize a VLS process for wire growth in nanoporous templates. To initiate the growth of a nanowire, a small catalytic gold seed is electrochemically deposited into the bottom of each AAO pore. The substrate is heated in hydrogen ambient to an appropriate temperature in a hot wall, low pressure chemical vapor deposition reactor and silane (SiH₄) gas is introduced. Thermal decomposition of silane on the gold seeds results in the formation of a liquid Au—Si eutectic and ultimately, in the precipitation and growth of single crystal silicon nanowires within the pores.

The fabrication of p-type and n-type silicon nanowire arrays with controlled resistivity has previously been demonstrated in using trimethylboron (TMB)ⁱ and phosphine dopant sources, respectively. For the radial p-n junctions, intentionally n-type doped epitaxial Si thin films are deposited on the outer surface of the p-type silicon nanowires to form a continuous layer by adjusting the growth conditions that enhance the Si thin film deposition rate. The core-shell p-n nanowire arrays are characterized using SEM and TEM to assess the structural properties and crystalline orientation.

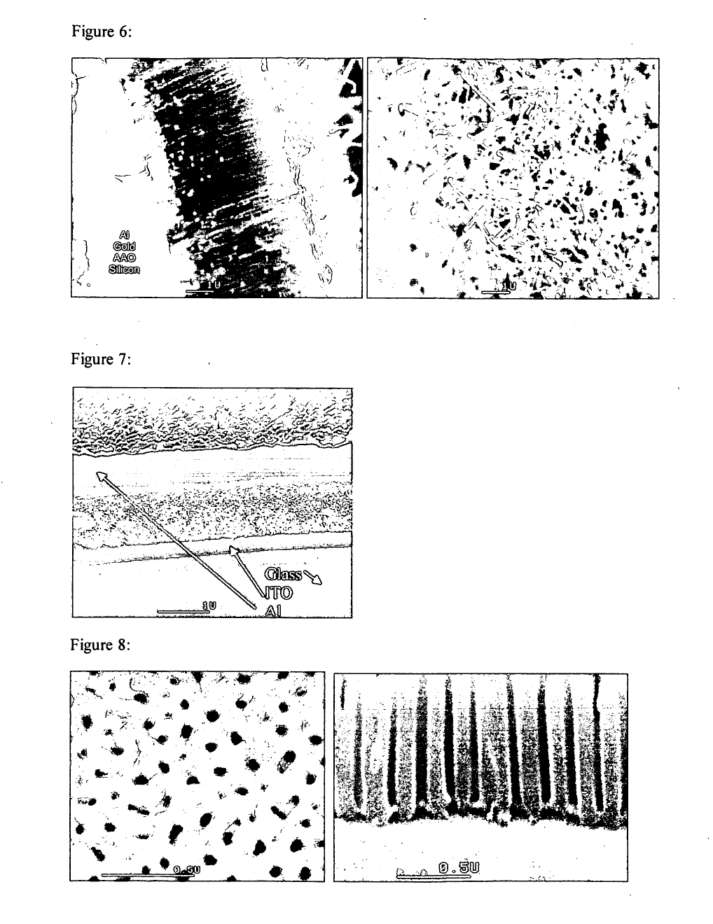

Gold is used as the catalytic seed material but alternate catalytic seeds may be used, including Sn, Al, In. Our previous engineering of silicon nanowire arrays has been successful and repeatable using both aluminum and ITO coated glass substrates. We have grown silicon nanowires on Al foils and on thin Al wire for possible use in a PV textile. In FIG. 6 we present an SEM micrograph showing silicon nanowires grown on an ITO coated glass substrate.

FIG. 7 shows a cross-sectional and top view of an anodized and Au seeded Al wire with Si nanowires. In FIG. 7, much more gold is present than necessary for nanowire synthesis. Both coated glass and Al foil substrates will be used. Other substrates like plastic, nylon, other polymers may also be used.

VLS growth has previously been used to synthesize silicon and other semiconductor nanowires using gold thin films or nanoparticles as catalysts supported on a substrate surface or produced within the gas phase. At low pressures and proper temperatures, the SiH₄ diffuses into the pores and preferentially decomposes on the catalytic surface rather than the surface or walls of the pore. A silicon nanowire is nucleated within the pore and grows upward and out of the top surface of the AAO. When properly engineered, the Si nanowires retain the AAO pore diameter after growing past the template surface. The wires can be controllably doped p-type through the addition of diborane (B₂H₆) during VLS growth. The length of wire extending beyond the top of the template will ultimately be the p-n junction.

After the p-n junctions are formed, a second conductive layer (electrode) is applied over the n-type layer to make a usable PV device. One embodiment utilizes a sputtered coated ITO film, however, ITO suffers from inherent brittleness, the necessity of a vacuum sputter deposition process, and high cost. Therefore, transparent conductive ink coatings consisting of carbon nanotubes bound in a polymer, Invisicon®, that is produced by Eikos Inc., can be used

The performance enhancements of the nanowire PV are achieved using low cost manufacturing processes that are suitable for high volume, high rate manufacture. Large foils of the aluminum, or coated glass plates, can be anodized and seeded using automated electrochemical equipment. The vapor growth of the nanowires is likely to be the most expensive process used; however, due to the low pressure used in the process, multiple substrates can be stacked in the CVD reactor in a single growth run, thereby improving the utilization of the hydride gas sources. In addition, the vapor growth process is more easily scaled to large areas than crystalline devices providing an economy of scale not available to crystalline device manufactures.

Furthermore, the potential for building large single sheet PV devices reduces the cost of panel construction. Much of the assembly cost associated with individual single crystal wafer based devices is removed. Panels of the nanowire array PV will likely be more expensive than their continuous process thin film counterparts, but the additional cost may be offset by a greater efficiency of the nanowire devices. Overall, the nanowire PV technology should reduce panel size, weight and, ultimately, total energy cost (cost of ownership).

Other semiconductors such as germanium and III-V materials can be used. A germanium nanowire array could serve as a template base for the growth of III-V materials over the nanowire surface to build multi-junction devices capable of extremely high conversion efficiency. Advanced development of the manufacturing process may lead to a roll-to-roll process that will produce very long, continuous sheets of nanowire PV devices similar to the processes used for thin film PV devices today by NanoSolar Corporation.

Aluminum foil (99.99% sheet) or glass coated with ITO (10-20 Ohms per square) or Al can be used as substrate materials. FIG. 8 shows an SEM image of an unprocessed glass substrate. Both substrate types have the desired characteristics of low-cost and the amenability to large area manufacture, with Al foil having the added trait of being a flexible platform. Conductive polymers may also be used. Additional substrate materials will be explored in Phase II including conductive polymers. Having the pores in the AAO completely penetrating the insulating Al₂O₃ barrier layer (FIG. 5) that is formed at the bottom of the pores during anodization is requisite to have an Ohmic connection between the conductive electrode on the substrate and the nanowires.

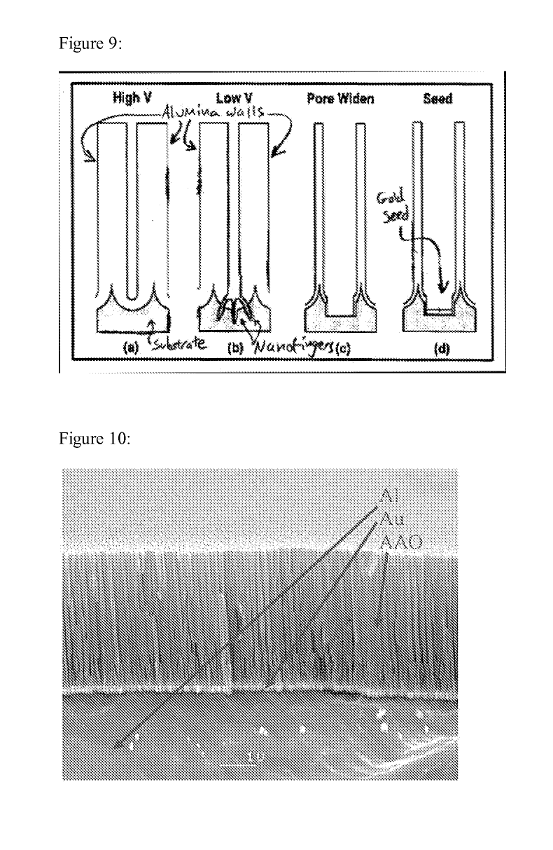

In a representative anodization process of Al on an ITO coated glass substrate, the Al layer is anodized in a solution of oxalic acid. The anodization is carried out until all the Al metal is consumed and the pores in the Al₂O₃ penetrate through to the ITO strike layer. Anodization is performed at 20-200 V dc. The diameter and center-to-center spacing of the pores are controlled by electrolyte concentration and type and these parameters are a linear function of the anodization voltage up to ˜200 V which corresponds to a 250 nm pore size in the Illuminex process. Saturation and stress effects determine this upper bound. As the Al₂O₃ pores begin to penetrate the ITO interface, the anodization current begins to increase. When the current reaches 2-3 times its steady state value, this indicates that the Al metal has been consumed and the anodization process is stopped. At this point the samples appear translucent, and the porous template structures are formed, as presented in FIG. 9. Following anodization, the pores are widened and remnant Al₂O₃ is cleared from the Al₂O₃/ITO interface in a 10 wt % solution of phosphoric acid.

The preparation of Al foil will be slightly different than the ITO/glass substrates primarily because the pores will have a more substantial Al₂O₃ barrier layer at the Al interface that has to be removed. High purity (99.99%) aluminum foils will be anodized in oxalic acid.

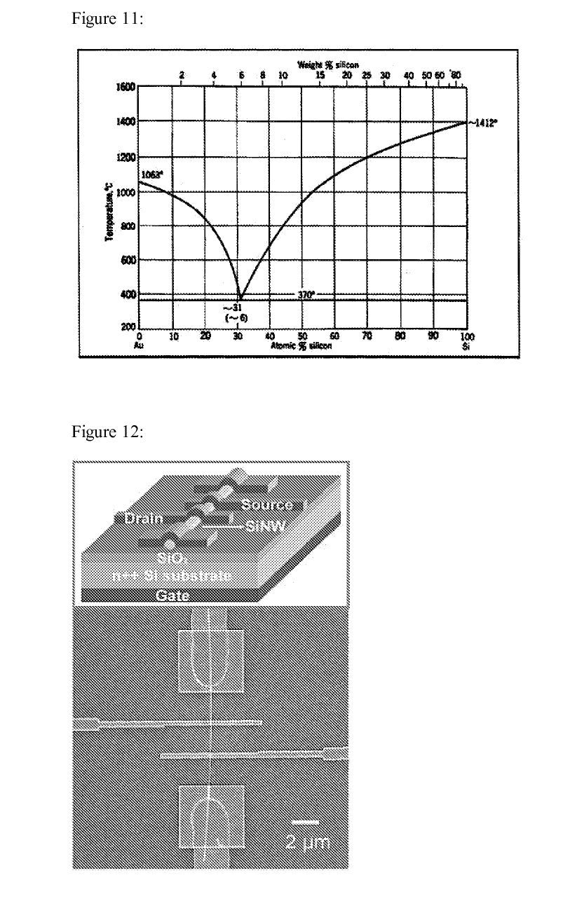

The first step in the process is to anodize Al at a constant “high” voltage (40-200 V) to form the base array of ˜30-60 nm diameter nanopores. This anodization is carried out until the pores reach the desired depth (2-5 μm). Once the desired depth is achieved, the anodization voltage is lowered in sequential steps of 1-10 volts at 1-5 minute intervals so that successively smaller nanofinger protuberances extend from the bottom of the pores into the Al₂O₃ barrier layer. This “step-down” anodization technique substantially thins the Al₂O₃ barrier layer, thus providing a path for the seed, and subsequently the nanowires, to make Ohmic contact with the substrate. After the anodization process has been completed, the nanoporous Al₂O₃ substrate will be cleaned in de-ionized water. Etching the Al₂O₃ in a 10 wt % phosphoric acid solution will both widen the pores and open them at the bottom, exposing the al metal. The anodization process is outlined schematically in FIG. 10. The substrate is prepared for nanowire growth once gold seeds are deposited in the nanochannels by electrodeposition as shown in FIG. 10(d).

In one embodiment, gold as a catalytic seed material is used. The seeds will be electrochemically deposited into the anodized pores using pulse plating. A function generator is used running a power supply and a sinusoidal or square wave with a positive offset and amplitude of 5-10 volts peak-to-peak at 0.5-25 kHz to electroplate gold nano-structures in porous AAO.

After seed deposition, the Al₂O₃ are etched from representative samples to determine the gold seed size and distribution throughout the substrate by SEM imaging. Previous work has demonstrated that a 1:1 diameter:height seed size will result in effective nanowire nucleation and a function of this task will be to optimize the electro-deposition parameters to achieve a uniform distribution of gold seeds with the minimal amount of catalytic material necessary to produce copious numbers of nanowires.

FIG. 11 shows an SEM micrograph of anodized Al foil substrate with gold seeds electro-plated into the bottom of the AAO pores in previous work by Illuminex. The ideal substrate may have a thinner oxide layer and less gold than shown in FIG. 9. Gold seeds are used for VLS growth of silicon nanowires, primarily due to the low Au—Si eutectic temperature (363° C.) and favorable wetting properties, which result in the formation of a stable liquid alloy phase at the nanowire tip. However, it is well known that gold can form deep level states within the bandgap of silicon which act as recombination centers for minority carriers in both p-type and n-type material. While the solid solubility of gold in silicon is low (<10¹³ cm⁻³) at temperatures typically used for VLS growth of silicon nanowires (˜500° C.), it is possible that metastable amounts of gold may be incorporated in the nanowire lattice since the silicon crystal precipitates out of a liquid gold melt in this growth process. It is envisioned that a trap density of 10¹⁴ or less will result in favorable PV behavior, however, it is nonetheless important to identify alternative metals that act as effective solvents for VLS growth of silicon nanowires without incorporation of electrically active impurities and compare their performance in devices with that of gold. Sn, In, or Al may be used as catalytic material.

Intentionally-doped p-type silicon nanowires can be grown by the vapor-liquid-solid (VLS) technique on the AAO-coated glass and aluminum foil substrates produced. We have previously demonstrated the synthesis of intentionally-doped p-type¹⁶ and n-type¹⁷ silicon nanowires in free-standing anodized alumina membranes. Nanowire growth is carried out in a low pressure (˜10 Torr), isothermal quartz tube reactor at 500° C. using SiH₄ (10% in H₂) as the silicon source and trimethylboron (2% in H₂) and phosphine (100 ppm in H₂) as p-type and n-type dopant sources, respectively. Nanowires grown under these conditions are predominantly single crystal with growth directions of <110>, <111> or <112> due to random nucleation of Si within the AAO pores.

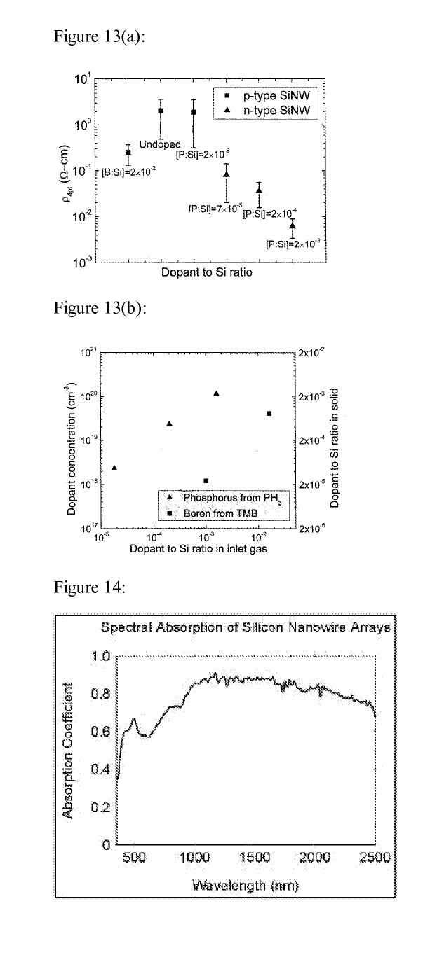

Four point resistance measurements are carried out on individual silicon nanowires removed from the AAO substrate and released into a solvent by mechanical agitation. A test bed structure (FIG. 13) that incorporates two large area electrodes for field-assisted placement of the nanowires into the test structure, a global metal back-gate for gated current-voltage measurements and two additional top contacts, fabricated by e-beam lithography, for four point resistance measurements are utilized. Carrier type and resistivity measurements of individual wires are used in combination with elemental analysis of dopant concentration (carried out using a large collection of silicon nanowires) by secondary ion mass spectrometry (SIMS) to study issues of dopant incorporation and compensation in the VLS-grown silicon nanowires produced during this task.

Previous work has shown that nanowire resistivity decreases with the addition of both boron and phosphorus dopants (FIG. 14 (a)), however, it is possible to obtain significantly lower resistivities in the n-type silicon nanowires compared to the p-type. This is due primarily to the higher doping efficiency of the PH₃ source compared to TMB at the conditions used for nanowire growth, as determined from the SIMS data (FIG. 14(b)). Nominally undoped silicon nanowires can be p-type, and the unintentional acceptors present in the wires compensate the phosphorus donors at low PH₃/SiH₄ ratios. The unintentional acceptors in the nominally undoped silicon nanowires likely originate from residual aluminum that is present in AAO membranes after the anodization process.

After VLS growth, the p-type nanowires will likely have some catalytic seed material left on their tips. This can be removed by a chemical etch but that would require removing the nanowire arrays from the reactor which would result in an undesirable oxidation of the silicon. Therefore, initially deposited is an n-type silicon layer on the outer surface of the p-type nanowires in the reactor immediately after VLS growth. This will be accomplished by introducing a short growth pause after VLS growth of the p-type silicon nanowires during which SiH₄ and TMB will be switched out of the reactor and the reactor temperature will be increased from 500° C. to 650° C. As demonstrated in our earlier work using SiH₄ as the source gas, higher growth temperatures lead to an increased rate of silicon thin film deposition compared to VLS growth. Consequently, by adjusting growth conditions we can switch between the regime where nanowire growth is dominant to one that is dominated by thin film deposition. In addition to the nanowire coating experiments, we will also prepare samples of n-type silicon thin films grown using varying PH₃/SiH₄ deposited on high resistivity silicon substrates. Hall measurements are carried out on the thin film samples in order to determine the resistivity and electron concentration of the n-type layers. This information can be used to determine the appropriate growth and doping conditions needed to fabricate the n-type shell layer over the p-type silicon nanowires.

Scanning electron microscopy is used to assess the initial structural properties of the nanowire samples including the nanowire diameter, length and density. Transmission electron microscopy is used to examine the crystallographic properties of nanowires with and without the n-type layers. To do this analysis, the nanowires are first released from the surface of the AAO into a solvent by mechanical agitation and are then dispersed onto copper TEM grids. TEM is used to assess the crystal quality of the p-type silicon nanowire core and the n-type silicon shell as well as the junction interfacial region.

An important task is the application of an upper electrode to the n-type surface and complete the PV circuit. Equally central to the nanowire junctions which create the photocarriers is the electrode design to extract the carriers with maximum effectiveness. In one embodiment, a thin gold or aluminum film is evaporated over the upper surface to provide electrical contact and measure the junction I-V characteristics. In another embodiment, transparent conductive coatings to measure both the I-V and photo-induced current characteristics are used.

When a silicon structure is reduced in size to the nanometer level (nanowire), the boundary effects become increasingly important. Additionally, due to the finite number of atoms present in the nanowire, new electronic, mechanical, and thermodynamic phenomena arise that are not observed in bulk silicon. It must be recognized that the presence or elimination of an oxide layer on the nanowire surface will have a profound effect on the performance of any device that utilizes the electro-optic properties of the silicon nanowire. Oxide layers forming on the silicon surface could prove deleterious to photocurrent collection. Thus, either the nanowires are conductively coated in-situ, or, a chemical etch is used to remove the oxide. One may also passivate the surface post silicon growth. Etching in a 2% HF solution or using Buffered Oxide Etch (BOE, Transene) will remove the oxide layer. This etch can also result in hydrogen termination that provides oxidation resistance (SiH₃ or SiH₂). Hydrogen termination may have a finite lifetime of stability; however, it appears long enough to apply a conductive coating.

ITO or silicon nitride can passivate the silicon surface, reducing surface recombination velocity, increasing the fill factor and increasing open the circuit voltage.

An embodiment has an upper electrode coating of ITO. For the initial electrical characterizations, the nanowire arrays are sputter coated with an ITO film 20-200 nm in thickness (10-20Ω/□) using the deposition process used to make the glass/ITO substrates. However, ITO suffers from inherent brittleness, the necessity of a vacuum sputter deposition process, and relative high cost. Another embodiment tuses a conductive coating consisting of carbon nanotubes bound in a polymer, Invisicon®, produced by Eikos Inc. that can be applied by dip or spray coating. This coating is highly flexible, can be spray or dip applied, and has greater than 90% visible light transmittance with a sheet resistance of 200Ω/κ. The coating is also robust. Tensile strain analysis has shown a 14% change in resistance at an 18% strain compared to a 20,000% change in resistance at a 3% strain for ITO films.

Methods of patterning a high conductivity metallic layer over the transparent conductor may be used to maximize photocurrent collection. In one embodiment, the devices are coated with silver paint to attach leads or spring loaded “pogo” probes. Other more sophisticated wiring techniques can be used to pattern leads on the surface of the samples or attach external electrodes using flexible polymer printed circuits to attach at many collection points on the sample.

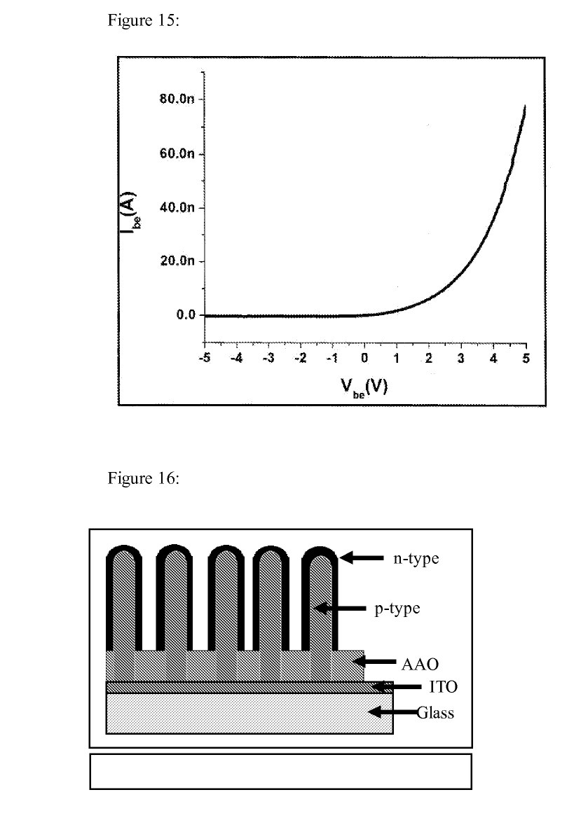

The optical properties of the silicon nanowire array will be measured to determine the efficiency of the absorption of the structure in the solar band. Unlike an antireflection coating, the “forest” structure of the nanowires in the matrix will effectively absorb solar radiation across the entire solar band when the array directly faces the source and when the source is at an angle relative to the plane of the array. When using the glass/ITO substrates the solar cell could possibly be illuminated from both sides of the plane. We have previously measured the absorption spectra of a silicon nanowire array, similar to the ones we propose here, and this data is presented in FIG. 15. The data were calibrated against a piece of identical substrate material lacking only silicon nanowires to show only the absorption due to the nanowires.

The expectation of enhanced absorption arises from the light trap structure of the nanowire array. Photons incident on any nanowire within the array may be absorbed, reflected or transmitted. Absorbed photons naturally contribute to the produced photocurrent. As discussed earlier, photons reflected from the shaped tops of the nanowires will be scattered into the wire matrix. Photons reflected from the surface of a nanowire will be reflected down the axis of the wire. The photons will therefore undergo multiple reflections as they continue through the matrix and have a high probability for being absorbed. This is true of photons arriving at virtually any angle of incidence, unlike the case of a tuned antireflection coating. Photons that manage to reach the bottom layer of aluminum or ITO will be reflected back and have a tortured path as well. These path changes effectively increase the effective optical thickness of the device as photons traverse through the nanowire array.

The optical properties of the nanowire array are measured at normal incidence, 15, 30, 45, 60 and 75 degrees off axis to determine the effectiveness of the array to absorb solar radiation. Measurements may be performed from a back side illumination. Measurements are taken on an IR-Vis-UV spectrograph at wavelengths from 3 μm to 300 nm. This spectral range covers the most important part of the solar spectrum for PV energy conversion. The data obtained from the measurements of several nanowire arrays with differing wire diameters and spacing are fed back into the growth process engineering to optimize the optical absorption of the array in the solar band. These results are compared to similar spectra of a bare silicon wafer and a commercial silicon solar cell with an antireflection coating. Measurements will be performed on p-type wire arrays without the to n-type layer deposition and after n-type layer deposition for comparison.

Electrical measurements can be conducted on individual silicon nanowires to determine how the dopant incorporation and minority carrier device properties depend on the processing parameters. A back-gated four-point test structure can be used to establish the relationship between inlet dopant to SiH₄ gas flow ratio, carrier type, and resistivity for silicon nanowires. This test structure is used to study silicon nanowires doped intentionally using PH₃, TMB, and B₂H₆ grown from Au catalysts deposited within the pores of alumina membranes as well as on the surface of planar SiO₂ substrates. These data are needed to select appropriate growth conditions (i.e., doping profile) to optimize device performance of solar cells based on semiconductor nanowires.

The diode characteristic of the device can be measured using a Tektronix 576 curve tracer scope. Successful junction creation results in rectifying behavior in the current-voltage (I-V) measurements. The I-V data will be analyzed to determine the ideality factor of the diode and the series resistance of the device. Measurements will be made on various size areas of substrates to establish the efficiency of junction creation and to determine defect densities.

Measurements of the I-V curves with a variable resistor in the circuit and the measurements will be performed with and without illumination. One can use a Newport model 96000, 150 W solar simulator light source for photo-response measurements. With the resistance of the circuit set to zero we determine the short-circuit current (Isc) and at maximum resistance, the open-circuit voltage (Voc).

The power produced by a PV-cell (P=IV) is greatest at the point (Iₘₚ, Vₘₚ) where mp=maximum power as traced on the I-V curve. FIG. 16 shows an I-V curve previously measured on a single axial junction nanowire. The maximum power is roughly at the bend in the curve, at the position where a rectangle drawn within the plot would have the greatest area. The quality of the PV devices we engineer will be assessed by the fill factor and the efficiency. The fill factor (FF), is the ratio of the PV maximum power to the product of the short-circuit current and open-current voltage. The fill factor is defined as FF=IₘₚVₘₚ/I_{SC}V_{OC}. The closer the value of the fill factor is to unity, the better the operation of the PV. The efficiency (η) of the PV is defined as η=P_{M}/L_{I}A where A is the active surface area of the cell, L_{I} is the calibrated light intensity and P_{M} is the maximum power. Thus, the I-V characteristics will be used to characterize and compare the nanowire PV devices.

The promise of enhancing solar cell efficiency using semiconductor nanowire-based device structures assumes that the minority carrier properties are comparable to those that can be achieved in planar structures. These properties are largely unmeasured in VLS-grown nanowires and have not been characterized for different materials, doping densities, diameters, or p-n junction device structures. Moreover, nanowire p-n junction solar cell arrays can utilize a combination of VLS and epitaxial thin film deposition to form the inner core and outer shell. In another embodiment, integrated individual axial and radial p-n junction silicon nanowire devices of different diameters can be used to characterize the dark and light I-V properties and determine the role of bulk and surface recombination in these devices. Our previous work in this area showed large differences in reverse leakage for p-n and n-p junctions, and forward current limited by series resistance due to poor contacts. Recently, we demonstrated low contact resistance to n⁺⁺-source/drain regions of axially-doped silicon nanowire field effect transistors. These techniques will be used to form low resistance contacts to our silicon nanowire p-n junctions and allow us to more accurately determine the factors that impact junction ideality factor and reverse leakage for different junction configurations.

The diameter of silicon nanowires causes radial p-n junctions to not obey bulk semiconductor theory. The width of the depletion region in Si can go from tens of nanometers for 10¹⁹ cm⁻³ doping to a few micrometers for 10¹⁵ cm⁻³ doping. With low level doping in the silicon nanowires (<mid-10¹⁷ cm⁻³), the entire junction is depleted and its current-voltage characteristics will not be resistive. If the doping is above 10¹⁸ cm⁻³, quantum tunneling becomes a significant conduction mechanism. The current-voltage characteristics will fail to show rectification, becoming a quasi-ohmic junction.

It is recognized that the creation of a p-type nanowire core with an n-type surface can be reversed so that an n-type core is surrounded by a p-type layer. In either case, a p-n junction is formed, which is where the photons create the carriers. The depth of the junction below the surface can range from 10 nanometers to 100 nanometers. The depth is determined by the chemical process of the doping the additional semiconducting layer. The deeper the junction, the longer the distance from the junction to the carrier collector on the top of the device. Therefore, the goal is a thinner layer that is sufficiently deep to have proper carrier generation and other electrical characteristics.

While the PCT/US06/023662, filed on 16 Jun. 2006, discloses as one embodiment a photovoltaic wire where the silicon nanowires are of one polarity and coated with a conductive polymer of opposite polarity, in this case, the semiconducting nano wires are doped at their surface to create a p-n junction below the surface of the nanowire, or an additional layer of opposite doping polarity is deposited. The nanowires are then coated with a transparent conductor. Any substrate can be used so long as a there is a conducting layer contacting the lower end of the semiconducting nanowires. In one embodiment, glass coated with a conducting film is used. Any insulator coated with a conducting film may be used as long as it provides a proper electrical connection to the base of the nanowires. Aluminum is very convenient because it is a conductor and can be anodized to create the template using the bulk material. Metals like Aluminum are convenient as substrates because metal sheets or foils can be bent into shapes prior to creating the nanowires. Alternatively, the nanowires can be grown on the metal sheet and the sheet shaped after production. In the latter case, Invisicon, rather than ITO may be the more convenient transparent conductor.

The application of the invention includes using heat to generate electricity, for thermo-photovoltaic devices or TPV. TPV require a low bandgap material which can be realized in the III-V family of semiconducting compounds. Examples are GaSb, GaInAsSb, InGaAs/InP, and GaInSb.

We have preliminary results demonstrating the vapor-liquid-solid (VLS) growth of GaSb nanowires on c-plane (0001) sapphire substrates using a metal-organic chemical vapor deposition (MOCVD) approach. Gold thin films (˜2-3 nm) and 50 nm gold nanoparticles deposited on sapphire were used as the catalysts for wire growth. Based on the gold-gallium and gold-antimony binary phase diagrams, a liquid eutectic phase, a requirement for VLS growth, is expected to form at temperatures above ˜375° C. Once the liquid phase becomes supersaturated with gallium and antimony, a single crystal nanowire is precipitated and the liquid metal droplet rides on the end of the nanowire and continues to feed the wire growth along the axial direction.

In the MOCVD process, trimethylgallium ((CH3)₃Ga, TMGa) and trimethylantimony ((CH3)3Sb, TMSb) were used as precursors with hydrogen as the carrier gas. GaSb nanowires were obtained within a narrow range of process conditions (˜480-500° C., V/III=0.5-1, Reactor pressure=100-300 Torr). Vertically-oriented GaSb nanowires (FIG. 2) were obtained for growth at 500° C., 300 Torr and V/III=1 using a gold thin film catalyst on sapphire. Transmission electron microscopy (TEM) and energy-dispersive x-ray spectroscopy (EDX) were used to carry out structural characterization and compositional analysis of GaSb nanowires released from the sapphire surface by mechanical agitation. The majority of the nanowires are single crystal with a <111> growth direction. The nanowires are homogeneous in composition and a gold tip is present at the end of the wire, indicative of VLS growth.

The nanowire resistivity and carrier type were determined from four-point measurements carried out on individual GaSb nanowires released from the substrate using a back-gated electrical test structure. Samples were fabricated by integrating the nanowires, suspended in isopropyl alcohol, onto silicon nitride-coated n++-Si substrates with pre-patterned Ti/Au electrodes using a field-assisted assembly technique. Top electrodes were defined by electron beam lithography followed by lift-off of thermally evaporated Ti(100 nm)/Au(100 nm) contacts. Prior to electrode metallization, the native oxide was removed by etching in dilute HCL.

When producing the photovoltaic device, a barrier layer must be maintained separating the n-type shell and the p-type nanowires. They must have separate electrodes that do not come in contact with each other. As shown in FIG. 16, the template can act as a non-conducting or insulating layer to prevent a short circuit from the substrate to the outer layer of the nanowire. In the preferred embodiment this is the AAO layer. Therefore any process to create a nanowire photovoltaic device must avoid damaging this insulator layer so that it acts as an insulator. The point is to maintain an insulator between the substrate and the outer sheath of the nanowires.

Often HF is used to remove the native oxide layer that will grow on the p-type nanowires during the process where the catalytic seeds are removed (i.e. the nanowires are exposed to air). However, the HF destroys the AAO layer making the device short out. An example of a process that avoids the use of HF is that in the step between p-type nanowire growth and n-type (or i-type and then n-type coating) the excess catalytic material must be removed in an oxygen free environment. Another alternative is to passivate the silicon with hydrogen prior to oxygen exposure. This will occupy the dangling bonds that may otherwise accept oxygen. Alternatively, other catalysts (Al, Sn) than gold may be used, which would not have to be etched off after nanowire growth. In that case, both the p-type nanowire growth and the n-type coating could be done in-situ, without breaking vacuum.

The key in this embodiment is to have an oxygen free layer between the p-n junction components in order to avoid the HF etch step and keep the integrity of the AAO insulating layer intact. We have demonstrated that the AAO will remain intact when HF is not used by using a liquid electrolyte as the n-type electrode. This did not short as it would have if any cracks, holes or other conductive paths large enough for a liquid to penetrate existed.

The following publications are incorporated herein by reference for all that they teach:
wwwl.eere.energy.gov/solar/solar_america/
S. J. Crowell, “PV as the Premium Energy Source: Securing Value,” UPEx 2001, Sacramento, Calif., 1-4 Oct. 2001.
M. Gratzel, Inorganic Chemistry, 44, 6841-6851 (2005).
M. Zukalova, A. Zukal, L. Kavan, M. Nazeeruddin, P. Liska and M. Gratzel, Nano Letters, 5, 1789-1792 (2005).
W. Huynh, J. Dittmer, and P. Alivisatos, Science, 295, 2425-2427 (2002).
G. Yu, J. Gao, J. Hummelen, F Wudl, and A. J. Heeger, Science, 270, 1789-1791 (1995).
B. Landi, R. Raffaelle, S. Castro, and S. Bailey, Progress in Photovoltaics: Research and Applications, 13, 165-172 (2005).
J. Nelson, Solid State and Materials Science, 6, 87-95 (2002).
M. Green, k. Emery, D. king, Y. Hisikawa, and W. Warta, Progress in Photovoltaics: Research and Applications, 14, 45-51 (2006)
B. Kayes, and H. Atwater, Journal of Applied Physics, 97, 114302 (2005).
G. Patermarakis, P. Lenas, Ch. Karavassilis, and G. Papayiannis, Electrochemica Acta, 36, 709 (1991).
F. Keller, M. Hunter, and D. Robinson, Journal of the Electrochemical Society, 411-419 (1953).
K. K. Lew, C. Reuther, A. H. Carim, J. M. Redwing and B. R. Martin, J. Vac. Sci. Technol. B 20, 389 (2002).
K. K. Lew and J. M. Redwing, J. Crystal Growth 254, 14 (2003).
T. Bogart, S. Dey, K. Lew, S. Mahoney, and J. Redwing, Advanced Materials, 17, 114-117 (2005).
K. Lew, L. Pan, T. Bogart, S. Dilts, E. Dickey, and J. Redwing, Applied Physics Letters, 85, 3101-3103 (2004).
Y. F. Wang, K. K. Lew, T. T. Ho, L. Pan, S. W. Novak, E. C. Dickey, J. M. Redwing and T. S. Mayer, Nano Lett. 5, 2137-2143 (2005).
J. Westwater, D. P. Gosain, S. Tomiya, and S. Usui, J. Vac. Sci. Tech. B 15, 554 (1997).
X. H. Fan, L. Xu, C. P. Li, Y. F. Zheng, C. S. Lee and S. T. Lee, Chem. Phys. Lett. 334, 229 (2001).
A. M. Morales and C. M. Lieber, Science 279, 208 (1998).
X. Duan, J. Wang, and C. M. Lieber, Appl. Phys. Lett. 76, 1116 (2000).
X. Duan and C. M. Lieber, Adv. Mat. 12, 298 (2000).
G. Patermarakis, P. Lenas, Ch. Karavassilis, and G. Papayiannis, Electrochemica Acta., 36, 709 (1991).
K. Shimuzu, K. Kobayashi, G. E. Thompson, and G. C. Wood, Philosophical Mag. A, 66, 643 (1991).
J. Weyher, “The Liquid Surface Tension as a Factor Influencing the VLS Growth of Silicon Crystals,” Mat. Sci. Eng. 20 (1975) pp. 171-177.
W. M. Bullis, “Properties of Gold in Silicon,” Solid State Electron. 9 143-168 (1966).
M. Tao, D. Udeshi, N. Basit, E. Maldonado, and W. P. Kirk, Applied Physics Letters, 82, 1559-1561 (2003).
X. H. Sun, S. D. Wang, n. B. Wong, D. D. D. Ma, and S. T. Lee, Inorganic Chemistry, 42, 2398-2402 (2003).
K. Peng, Y. Xu, Y. Wu, Y. Yan, S-T Lee, J. Zhu, Small, 1, 1062-1067 (2005).
C. M. Trottier, P. Glatkowski, P. Wallis, and J. Luo, Journal of the SID 13/9, 759-763 (2005).

The described embodiments of the invention are intended to be exemplary and numerous variations and modifications will be apparent to those skilled in the art. All such variations and modifications are intended to be within the scope of the present invention as defined in the appended claims. Although the present invention has been described and illustrated in detail, it is to be clearly understood that the same is by way of illustration and example only, and is not to be taken by way of limitation. It is appreciated that various features of the invention which are, for clarity, described in the context of separate embodiments may also be provided in combination in a single embodiment. Conversely, various features of the invention which are, for brevity, described in the context of a single embodiment may also be provided separately or in any suitable combination. It is appreciated that the particular embodiment described in the Appendices is intended only to provide an extremely detailed disclosure of the present invention and is not intended to be limiting.

The foregoing description discloses only exemplary embodiments of the invention. Modifications of the above disclosed apparatus and methods which fall within the scope of the invention will be readily apparent to those of ordinary skill in the art. Accordingly, while the present invention has been disclosed in connection with exemplary embodiments thereof, it should be understood that other embodiments may fall within the spirit and scope of the invention, as defined by the following claims.

What is claimed:

1. A photovoltaic device comprised of a plurality of nanowire semiconductor elements, where the diameter of the nanowires is between 50 to 300 nanometers and the length is between 10 and 100 microns, whereby the base of the nanowires are electrically connected to a first conductor at one end and a portion of the surface of the nanowires that includes the opposite end to said one end extend into a second conducting material, said semiconductor element having a p-n junction within it.

2. The device of claim 1 where the element has a semiconductor junction whose locus defines a surface that is enclosed within and substantially concentric to the physical surface of the element, whereby the physical surface of the element is of one semiconductor polarity and the interior of the element within the locus is of the opposite polarity.

3. The device of claim 1 where the distance from the junction to second conductor is between 10 and 500 nanometers.

4. The devices of claim 3 where the optical path of the photon before it is absorbed and creates a carrier pair can be greater than 10 microns.

5. Claim 1 using silicon as the semiconductor,

6. Claim 1 where the semiconductor is a material with a band gap.

7. Claim 6 where the band gap is a range of between 1.5 to 3.1 eV., for visible light.

8. Claim 1 where the semiconductor is gallium antinomide.

9. Claim 1 where the semiconductor has a band gap between 1 and 4 eV.

10. Claim 1 where the band gap is between 0.3 and 1 eV, for infrared.

11. Claim 1 where the band gap is 3 to 150 eV for ultraviolet.

12. Claim 1 where the band gap is approximately 1340 for X-rays.

13. Claim 2 further comprising an insulator layer preventing an electric current path from the physical surface of the nanowires to the first conductor.

14. Claim 13 where the insulator layer acts as a template through which the nanowires are grown.

15. Claim 14 where the insulator layer is a metal oxide.

16. Claim 15 where the metal oxide is alumina.
